(19) United States
(12) Patent Application Publication
(10) Pub. No.: US 2014/0117347 A1
(43) Pub. Date: May 1, 2014

(54) Thin Film Transistor and Active Matrix Flat Display Device

(71) Applicants: Cheng-Lung Chiang, Shenzhen City (CN); Po-Lin Chen, Shenzhen City (CN)

(72) Inventors: Cheng-Lung Chiang, Shenzhen City (CN); Po-Lin Chen, Shenzhen City (CN)

(73) Assignee: Shenzhen China Star Optoelectronics Technology Co., Ltd., Shenzhen (CN)

(21) Appl. No.: 13/700,499

(22) PCT Filed: Oct. 29, 2012
(86) PCT No.: PCT/CN12/83695

§ 371 Date: Nov. 28, 2012

(30) Foreign Application Priority Data
Oct. 25, 2012 (CN) 201210413171.8

(51) Int. Cl. H01L 29/786

(52) U.S. Cl. CPC H01L 29/7869
USPC 257/43

(57) ABSTRACT

The present invention discloses a thin film transistor and an active matrix flat display device, the thin film transistor comprising a gate electrode, a first insulating layer, a source electrode, a drain, and multiple oxide semiconductor layers, wherein, the multiple oxide semiconductor layers sequentially laminate between the source electrode, the drain electrode and the first insulating layer and comprise a first oxide semiconductor layer disposed close to the first layer and a second oxide semiconductor layer electrically connected with the source electrode and the drain electrode, and the resistivity of the first oxide semiconductor layer greater than 10⁴ Ω·cm, the resistivity of the second oxide semiconductor layer smaller than 1 Ω·cm. Therefore, it ensures normal operation of the thin film transistor in order to ensure the display quality of the active matrix flat panel display device.

### BACKGROUND OF THE INVENTION

1. Field of the Invention

The present invention relates to the field of display technology, and more particularly relates to a thin film transistor and an active matrix flat display device.

2. Description of Related Art

Currently, the oxide thin film transistor has been widely used in the high-frequency displays and the high-resolution display products because of low required temperature for manufacturing and high electron mobility advantage.

The oxide thin film transistor technology is to replace the original silicon semiconductor material with an oxide semiconductor such as an IGZO (Indium Gallium Zinc oxide) to form a TFT semiconductor layer.

However, the semiconductor layer formed by the IGZO is easily influencing by the H-based bonds (the bonds containing a hydrogen element). When a GI layer (gate insulating layer) containing higher N—H bonds (nitrogen-hydrogen bonds), it will produce high GI/IGZO interfacial trap density (density of interface traps), resulting in abnormal electrical properties of the oxide thin film transistor.

### SUMMARY OF THE INVENTION

The main technical problem solved by the present invention is to provide a thin film transistor and an active matrix flat display device. It can effectively block the influence caused by the hydrogen bonds containing in the gate insulating layer. Therefore, it ensures normal operation of the thin film transistor and the display quality of the active matrix flat panel display device.

In order to solve the above-mentioned technical problem, a technical solution provided by the present invention is: a thin film transistor comprising: a gate electrode; a first, insulating layer disposed on the gate electrode; a source electrode and a drain electrode respectively disposed on the first insulating layer; and

multiple oxide semiconductor layers sequentially laminated between the source electrode, the drain electrode and the first insulating layer, wherein, a composition of each of the oxide semiconductor layers comprises at least one of a zinc oxide, a tin oxide, an indium oxide and a gallium oxide, and the multiple oxide semiconductor layers comprise a first oxide semiconductor layer disposed close to the first insulating layer and a second oxide semiconductor layer electrically connected with the source electrode and the drain electrode, and the resistivity of the first oxide semiconductor layer greater than 10⁴ Ω·cm, the resistivity of the second oxide semiconductor layer smaller than 1 Ω·cm, the content of oxygen in the first oxide semiconductor layer higher than the content of oxygen in the second oxide semiconductor layer.

Wherein, a carrier concentration of the first oxide semiconductor layer is less than 1×10¹⁵ cm⁻³, and a carrier concentration of the second oxide semiconductor layer is greater than 1×10¹⁸ cm⁻³

In order to solve the above-mentioned technical problem, another technical solution provided by the present invention is: a thin film transistor comprising: a gate electrode; a first insulating layer disposed on the gate electrode; a source electrode and a drain electrode respectively disposed on the first insulating layer; and

multiple oxide semiconductor layers sequentially laminated between the source electrode, the drain electrode and the first insulating layer, wherein, the multiple oxide semiconductor layers comprise a first oxide semiconductor layer disposed close to the first insulating layer and a second oxide semiconductor layer electrically connected with the source electrode and the drain electrode, and the resistivity of the first oxide semiconductor layer greater than 10⁴ Ω·cm, the resistivity of the second oxide semiconductor layer smaller than 1 Ω·cm.

Wherein, the content of oxygen in the first oxide semiconductor layer

higher than the content of oxygen in the second oxide semiconductor layer.

Wherein, a carrier concentration of the second oxide semiconductor layer is greater than 1×10¹⁸ cm⁻³.

Wherein, a carrier concentration of the first oxide semiconductor layer is less than 1×10¹⁵ cm⁻³.

Wherein, a composition of each of the oxide semiconductor layers comprises at least one of a zinc oxide, a tin oxide, an indium oxide and a gallium oxide.

In order to solve the above-mentioned technical problem, another technical solution provided by the present invention is: An active matrix flat panel display device, wherein, the device comprises an array substrate, the array substrate comprising: a base substrate; a gate electrode; a first insulating layer disposed on the gate electrode; a source electrode and a drain electrode respectively disposed on the first insulating layer; and

multiple oxide semiconductor layers sequentially laminated between the source electrode, the drain electrode and the first insulating layer, wherein, the multiple oxide semiconductor layers comprise a first oxide semiconductor layer disposed close to the first insulating layer and a second oxide semiconductor layer electrically connected with the source electrode and the drain electrode, and the resistivity of the first oxide semiconductor layer greater than 10⁴ Ω·cm, the resistivity of the second oxide semiconductor layer smaller than 1 Ω·cm.

Wherein, the content of oxygen in the first oxide semiconductor layer higher than the content of oxygen in the second oxide semiconductor layer.

Wherein, a carrier concentration of the second oxide semiconductor layer is greater than 1×10^{18 cm}⁻³

Wherein, a carrier concentration of the first oxide semiconductor layer is less than 1×10¹⁵ cm⁻³.

Wherein, a composition of each of the oxide semiconductor layers comprises at least one of a zinc oxide, a tin oxide, an indium oxide and a gallium oxide.

The beneficial effects of the present invention are: comparing with the prior art, the multiple oxide semiconductor layers sequentially laminate between the source electrode, the drain electrode and the first insulating layer, and the resistivity of the first oxide semiconductor layer disposed at the lowest layer of the multiple oxide semiconductor layers and close to the first insulating layer is greater than 10⁴ Ω·cm, and the resistivity of the second oxide semiconductor layer disposed on the first oxide semiconductor layer is smaller than 1 Ω·cm. Because the large resistivity difference of the first oxide semiconductor layer and the second oxide semiconductor layer, a carrier channel will be formed at the homogeneity interface between the first oxide semiconductor layer and the second oxide semiconductor layer when the thin film transistor is operating. It can effectively enhance the electron mobility of the thin film transistor. At the same time, the first oxide semiconductor layer can effectively block the influence caused by the hydrogen bonds containing in the first insulating layer. Therefore, it ensures normal operation of the thin film transistor in order to ensure the display quality of the active matrix flat panel display device.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the skilled persons of ordinary skill in the art without creative effort, it can also obtain other figures according to these figures.

FIG. 1 is a schematic view of a thin film transistor according to an embodiment the present invention;

FIG. 2 is a schematic view of an active matrix flat panel display device according to an embodiment of present invention; and

FIG. 3 is a schematic view of the array substrate of the active matrix fiat panel display device shown in FIG. 2.

### DETAILED DESCRIPTION OF THE PREFERRED EMBODIMENT

The following content combines figures and embodiments for detail description of the present invention.

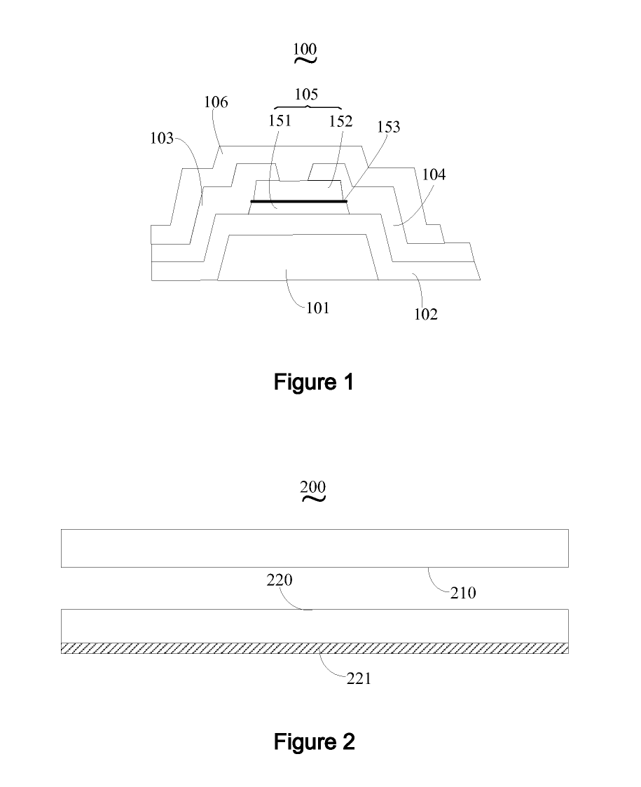

With reference to FIG. 1, it is a schematic view of a thin film transistor according to an embodiment the present invention. As shown in FIG. 1, a thin film transistor 100 of the present invention includes a gate electrode 101, a first insulating layer 102, a source electrode 103, a drain electrode 104 and multiple oxide semiconductor layers 105.

In this embodiment, the first insulating layer 102 is a gate insulating layer, which is disposed on the gate electrode 101. The source electrode 103 and the drain electrode 104 are respectively disposed on the first insulating layer 102. Therefore, the insulating, layer 102 electrically insulates the gate electrode 101, the source electrode 103 and the drain electrode 1104. In order to obtain better stability of the device, the present embodiment of the invention preferably selects SiOx (silicon oxide) which contains less hydrogen element for the first insulating layer 102.

In this embodiment, the multiple oxide semiconductor layers 105 function as a switch of the thin film transistor 100. When the multiple oxide semiconductor layers 105 are turned on, the source electrode 103 and the drain electrode 104 are electrically connected. When the multiple oxide semiconductor layers 105 are turned off, the source electrode 103 and the drain 104 are electrically disconnected. Wherein, the multiple oxide semiconductor layers 105 are sequentially laminated between the source electrode 103, the drain electrode 104 and the first insulating layer 102. In this embodiment, the multiple oxide semiconductor layers 105 preferably include a first oxide semiconductor layer 151 and a second oxide semiconductor layer 152.

Wherein, the first oxide semiconductor layer 151 is disposed at the lowest layer of the multiple oxide semiconductor layers 105 and is close to the first insulating layer 102. The second oxide semiconductor layer 152 is disposed on the first oxide semiconductor layer 151 and electrically connects with the source electrode 103 and the drain electrode 104. Between the first oxide semiconductor layer 151 and the second oxide semiconductor layer 152, it includes an interface 153.

In this embodiment, the resistivity of the first oxide semiconductor layer 151 is greater than 10⁴ Ω·cm, the resistivity of the second oxide semiconductor layer 152 is smaller than 1 Ω·m, and the content of oxygen in the first oxide semiconductor layer 151 is higher than the content of oxygen in the second oxide semiconductor layer 152. Therefore, a carrier concentration of the first oxide semiconductor layer 151 is less than a carrier concentration of the second oxide semiconductor layer 152. In the present embodiment, the carrier concentration of the first oxide semiconductor layer 151 is preferably less than 1×10¹⁵ cm⁻³, and the carrier concentration of the second oxide semiconductor layer 152 is preferably greater than 1×10¹⁸ cm⁻³. Due to the large resistivity difference of the first oxide semiconductor layer 151 and the second oxide semiconductor layer 152. Therefore, when the thin film transistor 100 is operating, a carrier channel will be formed at the interface 153.

In other embodiments, when the multiple oxide semiconductor layers 105 includes two or more oxide semiconductor layers, the content of oxygen of the first oxide semiconductor layer 151 is preferably the highest.

In this embodiment, a composition of the first oxide semiconductor layer 151 and a composition of the second oxide semiconductor layer 152 include at least one of a zinc oxide (ZnOx), a tin oxide (SnOx), an indium oxide (InOx) and a gallium oxide (GaOx). The first oxide semiconductor layer 151 and the second oxide semiconductor layer 152 have different contents of oxygen. Thus, it forms the homogeneity interface 153 with fewer defects. Carrier moving in the homogeneity interface 153 with fewer defects can effectively enhance the electron mobility of the thin film transistor 100.

Furthermore, a second insulating layer 106 is disposed on the source electrode 103 and the drain electrode 104, and the second insulating layer 106 is contact with the second oxide semiconductor layer 152. The second insulating layer 106 is used to prevent the source electrode 103, drain 104, and the second oxide semiconductor layer 152 from influencing by electrical properties or external environment.

The following describes the operation principle of the thin film transistor 100:

In the present embodiment, the gate electrode 101 functions as a control electrode of the thin film transistor 100, and the source electrode 103 functions as an input electrode of the thin film transistor 100, and the drain 104 functions as an output electrode of the thin film transistor 100. When a signal is inputted to the gate electrode 101, the thin film transistor 100 is turned on. The carrier channel is formed in the interface 153 between the first oxide semiconductor layer 151 and the second oxide semiconductor layer 152, and the source electrode 103 and the drain electrode 104 are electrically connected. The source 103 receives a drive signal from an external terminal and transmits the drive signal to the drain electrode 104 through the carrier channel. The electrons which respond for transmitting the drive signal are moving in the homogeneity interface 153 with fewer defects. Therefore, it improves the electron mobility for transmitting the drive signal. Furthermore, in the process of moving the electrons, the first oxide semiconductor layer 151 having the resistivity greater than 10⁴ Ω·cm blocks the influence caused by hydrogen bonds containing in the first insulating layer 102, that is, to prevent the moving electrons in the carrier channel from the influence caused by the hydrogen bonds. Thereby, it ensures normal operation of the thin film transistor 100.

With reference to FIG. 2, it is a schematic view of an active matrix flat panel display device according to an embodiment of present invention. As shown in FIG. 2, the active matrix flat panel display device 200 of the present invention comprises a color filter substrate 210 and an array substrate 220 disposed relatively to the color filter substrate 210.

In this embodiment, the array substrate 220 includes a base substrate 221. The material of the substrate 221 is preferably glass. Through coating and etching process on the substrate 221, main components of scan lines, data lines, pixel electrodes and thin film transistors are formed on the substrate 221.

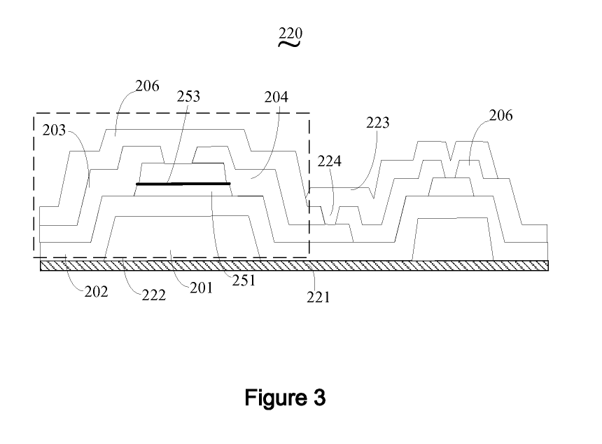

With reference to FIG. 3, it is a schematic view of the array substrate of the active matrix flat panel display device shown in FIG. 2. The array substrate 220 includes the base substrate 221, a thin film transistor 222, and a transparent conductive layer 723.

Wherein, in the present embodiment, the thin film transistor 222 is the same as the thin film transistor 100 shown in FIG. 1. Their specific structure is not discussed again. The transparent conductive layer 223 is disposed on a second insulating layer 206 and a position of the second insulating layer 206 corresponding to a drain electrode 204 is provided with a through hole 224 such that the transparent conductive layer 223 electrically connects to the drain electrode 204 of the thin film transistor 222 through the through hole 224. Wherein, the transparent conductive layer 223 functions as a pixel electrode of the array substrate 220.

When the thin film transistor 222 is turned on, the source electrode 203 transmits a drive signal to the drain electrode 204 through a carrier channel in an interface 253. The drain electrode 204 further provides the drive signal to the transparent conductive layer 223, and the transparent conductive layer 223 precedes a corresponding grayscale display according to the received drive signal in order to achieve display of the active matrix flat panel display device 200.

It should be noted that, when the source electrode 203 transmits the drive signal to the drain electrode 204, a first oxide semiconductor layer 251 having the resistivity greater than 10⁴ Ω·cm blocks the influence caused by hydrogen bonds containing in a first insulating layer 202. Thus, it ensures that the electrical properties of the thin film transistor 222 is normal, and ensures the display quality or the active matrix flat panel display device 200.

In summary, the multiple oxide semiconductor layers sequentially laminate between the source electrode, the drain electrode and the first insulating layer, and the resistivity of the first oxide semiconductor layer disposed at the lowest layer of the multiple oxide semiconductor layers and close to the first insulating layer is greater than 10⁴ Ω·cm, and the resistivity of the second oxide semiconductor layer disposed on the first oxide semiconductor layer is smaller than 1 Ω·cm. Because the large resistivity difference of the first oxide semiconductor layer and the second oxide semiconductor layer, a carrier channel will be formed at the homogeneity interface between the first oxide semiconductor layer and the second oxide semiconductor layer when the thin film transistor is operating. It can effectively enhance the electron mobility of the thin film transistor. At the same time, the first oxide semiconductor layer can effectively block the influence caused by the hydrogen bonds containing in the first insulating layer. Therefore, it ensures normal operation of the thin film transistor in order to ensure the display quality of the active matrix flat panel display device.

The above embodiments of the present invention are not used to limit the clams of this invention. Any use of the content in the specification or in the drawings of the present invention which produces equivalent structures or equivalent processes, or directly or indirectly used in other related technical fields is still covered by the claims in the present invention.

What is claimed is:

1. A thin film transistor comprising:
a gate electrode;
a first insulating layer disposed on the gate electrode;
a source electrode and a drain electrode respectively disposed on the first insulating layer; and
multiple oxide semiconductor layers sequentially laminated between the source electrode, the drain electrode and the first insulating layer, wherein, a composition of each of the oxide semiconductor layers comprises at least one of a zinc oxide, a tin oxide, an indium oxide and a gallium oxide, and the multiple oxide semiconductor layers comprise a first oxide semiconductor layer disposed close to the first insulating layer and a second oxide semiconductor layer electrically connected with the source electrode and the drain electrode, and the resistivity of the first oxide semiconductor layer greater than 10⁴ Ω·cm, the resistivity of the second oxide semiconductor layer smaller than 1 Ω·cm, the content of oxygen in the first oxide semiconductor layer higher than the content of oxygen in the second oxide semiconductor layer.

2. The thin film transistor according to claim 1, wherein, a carrier concentration of the first oxide semiconductor layer is less than 1×10¹⁵ cm⁻³, and a carrier concentration of the second oxide semiconductor layer is greater than 1×10¹⁸ cm⁻³.

3. A thin film transistor comprising:
a gate electrode;
a first insulating layer disposed on the gate electrode;
a source electrode and a drain electrode respectively disposed on the first insulating layer; and
multiple oxide semiconductor layers sequentially laminated between the source electrode, the drain electrode and the first insulating layer, wherein, the multiple oxide semiconductor layers comprise a first oxide semiconductor layer disposed close to the first insulating layer and a second oxide semiconductor layer electrically connected with the source electrode and the drain electrode, and the resistivity of the first oxide semiconductor layer greater than 10⁴ Ω·cm, the resistivity of the second oxide semiconductor layer smaller than 1 Ω·cm.

4. The thin film transistor according to claim 3, wherein, the content of oxygen in the first oxide semiconductor layer higher than the content of oxygen in the second oxide semiconductor layer.

5. The thin film transistor according to claim 3, wherein, a carrier concentration of the second oxide semiconductor layer is greater than 1×10¹⁸ cm⁻³.

6. The thin film transistor according to claim 3, wherein, a carrier concentration of the first oxide semiconductor layer is less than 1×10¹⁵ cm⁻³.

7. The thin film transistor according to claim 3, wherein, a composition of each of the oxide semiconductor layers comprises at least one of a zinc oxide, a tin oxide, an indium oxide and a gallium oxide.

8. An active matrix flat panel display device, wherein, the device comprises an array substrate, the array substrate comprising:
a base substrate;
a gate electrode;
a first insulating layer disposed on the gate electrode;
a source electrode and a drain electrode respectively disposed on the first insulating layer; and
multiple oxide semiconductor layers sequentially laminated between the source electrode, the drain electrode and the first insulating layer, wherein, the multiple oxide semiconductor layers comprise a first oxide semiconductor layer disposed close to the first insulating layer and a second oxide semiconductor layer electrically connected with the source electrode and the drain electrode, and the resistivity of the first oxide semiconductor layer greater than 10⁴ Ω·cm, the resistivity of the second oxide semiconductor layer smaller than 1 Ω·cm.

9. The active matrix flat panel display device according to claim 8, wherein, the content of oxygen in the first oxide semiconductor layer higher than the content of oxygen in the second oxide semiconductor layer.

10. The active matrix flat panel display device according to claim 8, wherein, a carrier concentration of the second oxide semiconductor layer is greater than 1×10¹⁸ cm⁻³

11. The active matrix flat panel display device according to claim 8, wherein, a carrier concentration of the first oxide semiconductor layer is less than 1×10¹⁵ cm⁻³.

12. The active matrix flat panel display device according to claim 8, wherein, a composition of each of the oxide semiconductor layers comprises at least one of a zinc oxide, a tin oxide, an indium oxide and a gallium oxide.
